(19) United States
(12) Patent Application Publication
(10) Pub. No.: US 2016/0028369 A1
(43) Pub. Date: Jan. 28, 2016

(54) RESONATOR ELEMENT, RESONATOR, OSCILLATOR, ELECTRONIC APPARATUS, AND MOBILE OBJECT

(71) Applicant: Seiko Epson Corporation, Tokyo (JP)

(72) Inventor: Yusuke YAMAMOTO, Minowa (JP)

(21) Appl. No.: 14/808,221

(22) Filed: Jul. 24, 2015

(30) Foreign Application Priority Data
Jul. 25, 2014 (JP) 2014-151566

(51) Int. Cl. H03H 9/19; H03B 28/00

(52) U.S. Cl. CPC H03H 9/19; H03B 28/00

(57) ABSTRACT

A resonator element includes a substrate region sandwiched by first and second excitation electrodes. The region is located within a quadrangle having four 90° corners, a pair of first sides along a thickness-shear vibration direction, and a pair of second sides perpendicular to the vibration direction. The region includes a side or a circular arc in contact with each of the first and second sides, and an outer edge recessed from at least two corners of the quadrangle in a direction intersecting the vibration direction. Further, assuming a maximum length of the region along the vibration direction is Lx, and a length of the outer edge along the vibration direction is lx, 13.7%≦(lx/Lx)≦46.0%.

### BACKGROUND

1. Technical Field

The present invention relates to a resonator element, and a resonator, an oscillator, an electronic apparatus, and a mobile object each provided with the resonator element.

2. Related Art

An AT-cut quartz crystal resonator vibrating in a thickness-shear vibration mode as a principal vibration mode is suitable for miniaturization and high frequency. The AT-cut quartz resonator also has a frequency-temperature characteristic showing an excellent cubic curve. In view of the foregoing, an AT-cut quartz resonator is used in a variety of fields such as oscillators and electronic equipment. In particular, in recent years, due to the increase in processing speed of transmission communication equipment and OA equipment, or the increase in communication data capacity and processing amounts, a demand for increasing the frequency to the AT-cut quartz crystal resonator used as a reference frequency signal source is increasing. In general, in order to realize the AT-cut quartz crystal resonator with a higher frequency vibrating in the thickness-shear vibration mode, the thickness of the vibrating portion is decreased to thereby achieve the higher frequency.

However, if the thickness of the vibrating portion is decreased for achieving the higher frequency, there arises a problem that the adjustment sensitivity of the frequency increases to degrade the frequency tuning accuracy, and thus the production yield of the resonator is degraded. To cope with this problem, JP-A-2002-111435 discloses that in a resonator of a temperature compensated oscillator, by roughly evenly cutting out the four corners of a rectangular excitation electrode so as to have the area ratio of 95% through 98% to the area before cutting, the capacitance ratio γ (=C0/C1; here, C0 represents an equivalent parallel capacitance, and C1 represents an equivalent series capacitance) of the resonator can be decreased, and thus the frequency variable sensitivity is increased. As a result, the margin in tuning the oscillating frequency can be increased.

However, the resonator described in JP-A-2002-111435 can ensure the capacitance ratio γ just enough to tune the oscillating frequency of the temperature compensated oscillator, but cannot sufficiently reduce the capacitance ratio γ in some cases as the resonator of the voltage-controlled oscillator required to have a higher frequency variable sensitivity only with the chamfered shape.

### SUMMARY

An advantage of some aspects of the invention is to solve at least a part of the problems described above, and the invention can be implemented as the following forms or application examples.

### APPLICATION EXAMPLE 1

This application example is directed to a resonator element including a substrate having a first principal surface and a second principal surface opposite to each other respectively forming an obverse (front) surface and a reverse surface of the substrate, a first excitation electrode disposed on the first principal surface, and a second excitation electrode disposed on the second principal surface, and overlapping an entirety of the first excitation electrode in a plan view (also referred to herein as the “planar” view), wherein the first excitation electrode is configured by forming at least one truncated corner to a rectangular shape, and the rectangular shape is configured with a pair of first sides extending in a first direction and a pair of second sides extending in a second direction perpendicular to the first direction in the planar view, wherein Lx is a maximum length of the first excitation electrode in the first direction and lx is a length of the one truncated corner in the first direction, the following relationship is fulfilled: 13.7%≦(lx/Lx)≦46.0%. Further, the one truncated corner can be in an arc shape.

According to this application example, in the region sandwiched by the first excitation electrode and the second excitation electrode, by adopting the excitation electrode structure of cutting out (removing) at least one of the four corners of the virtual quadrangle not making a contribution to the thickness-shear vibration, and further, assuming that the maximum length along the vibration direction of the thickness-shear vibration is Lx, and the length of the outer edge portion along the vibration direction of the thickness-shear vibration is lx, adopting an excitation electrode structure in which the dimensional ratio (lx/Lx) fulfills the relationship of 13.7%≦(lx/Lx)≦46.0%, it is possible to remove unwanted capacitance caused in a region not making a contribution to the thickness-shear vibration, efficiently confine the vibration energy of the thickness-shear vibration, increase the equivalent series capacitance C1, and decrease the equivalent parallel capacitance C0 determined by the area of the excitation electrode, and therefore, there is an advantage that the resonator element low in capacitance ratio γ can be obtained.

### APPLICATION EXAMPLE 2

This application example is directed to the resonator element according to the application example described above, wherein the following relationship is fulfilled: 19.1%≦(lx/Lx)≦41.0%.

According to this application example, by adopting the excitation electrode structure in which the dimensional ratio (lx/Lx) fulfills the relationship of 19.1%≦(lx/Lx)≦41.0%, it is possible to remove a larger amount of unwanted capacitance caused in the region not making a contribution to the thickness-shear vibration, and more efficiently confine the vibration energy of the thickness-shear vibration, and therefore, the resonator element lower in capacitance ratio γ can be obtained.

### APPLICATION EXAMPLE 3

This application example is directed to the resonator element according to the application example described above, wherein when S1 is an area of the rectangular shape and S2 is an area of the first excitation electrode, the following relationship is fulfilled: 79.8%≦(S2/S1)≦95.3%.

According to this application example, in the region sandwiched by the first excitation electrode and the second excitation electrode, by adopting the excitation electrode structure of cutting out at least one of the four corners of the virtual quadrangle not making a contribution to the thickness-shear vibration, and further, assuming that the area of the virtual quadrangle is S1, and the area of the first excitation electrode is S2, adopting an excitation electrode structure in which the area ratio (S2/S1) fulfills the relationship of 79.8%≦(S2/S1)≦95.3%, it is possible to remove unwanted capacitance caused in a region not making a contribution to the thickness-shear vibration, efficiently confine the vibration energy of the thickness-shear vibration, increase the equivalent series capacitance C1, and decrease the equivalent parallel capacitance C0 determined by the area of the excitation electrode, and therefore, the resonator element low in capacitance ratio γ can be obtained.

### APPLICATION EXAMPLE 4

This application example is directed to the resonator element according to the application example described above, wherein the following relationship is fulfilled: 81.3%≦(S2/S1)≦93.6%.

According to this application example, by adopting the excitation electrode structure in which the area ratio (S2/S1) fulfills the relationship of 81.3%≦(S2/S1)≦93.6%, it is possible to remove a larger amount of unwanted capacitance caused in the region not making a contribution to the thickness-shear vibration, and more efficiently confine the vibration energy of the thickness-shear vibration, and therefore, the resonator element lower in capacitance ratio γ can be obtained.

### APPLICATION EXAMPLE 5

This application example is directed to the resonator element according to the application example described above, wherein when lz is a length of the one truncated corner in the second direction, the following relationship is fulfilled: lx≧lz.

According to this application example, in the case of using the substrate in which the displacement distribution in the displacement direction determined by the crystal anisotropy and the displacement distribution in a direction intersecting with the displacement direction are different from each other, in particular in the case of exciting the thickness-shear vibration in the substrate using quartz crystal as the chief material, since the length of the displacement distribution in the displacement direction of the thickness-shear vibration is longer compared to the length of the displacement distribution in the intersecting direction. Therefore, by making lx as the length in the displacement direction of the vibration longer than lz in the length lx and the length lz of the outer edge section for cutting out at least one of the four corners of the virtual quadrangle, the efficiency of the confinement of the vibration energy can be improved, and therefore, the equivalent series capacitance C1 is increased, and the capacitance ratio γ of the resonator element can be made lower.

### APPLICATION EXAMPLE 6

This application example is directed to the resonator element according to the application example described above, wherein when Lz is a maximum length of the first excitation electrode in the second direction, the following relationship is fulfilled: 1.25≦(Lx/Lz)≦1.31.

According to this application example, in the case of using the substrate in which the displacement distribution in the displacement direction determined by the crystal anisotropy and the displacement distribution in the direction intersecting with the displacement direction are different from each other, in particular in the case of exciting the thickness-shear vibration in the substrate using quartz crystal as the chief material, the length of the displacement distribution in the displacement direction of the thickness-shear vibration is longer than the length of the displacement distribution in the intersecting direction. Therefore, by fulfilling the relationship of 1.25≦(Lx/Lz)≦1.31 in which Lx as the length in the displacement direction of the vibration becomes longer than the length Lz in the intersecting direction, since the efficiency of the confinement of the vibration energy can be improved, the equivalent series capacitance C1 is increased, and thus the capacitance ratio γ of the resonator element can further be lowered.

### APPLICATION EXAMPLE 7

This application example is directed to the resonator element according to the application example described above, wherein when S0 is an area of the substrate, the following relationship is fulfilled: 4%≦(S2/S0)≦50%.

According to this application example, by making the area ratio (S2/S0) between the area S2 of the first excitation electrode and the area S0 of the substrate fulfill the relationship of 4%≦(S2/S0)≦50%, the resonator element 1 stably vibrating and small in size can be obtained.

### APPLICATION EXAMPLE 8

This application example is directed to the resonator element according to the application example described above, further including a first lead electrode disposed on the first principal surface, the first lead electrode being connected to the first excitation electrode, wherein the first lead electrode overlaps with the second excitation electrode in the plan view.

According to this application example, the resonator element small in size can be obtained.

### APPLICATION EXAMPLE 9

This application example is directed to the resonator element according to the application examples described above, wherein the first direction is parallel to a vibration direction of the thickness-shear vibration.

According to this application example, the resonator element superior in frequency temperature characteristics can be obtained.

### APPLICATION EXAMPLE 10

This application example is directed to the resonator element according to the application example described above, wherein a thick-wall section disposed integrally with an outer edge of the substrate, and larger in thickness than the substrate is provided.

According to this application example, by disposing the thick-wall section larger in thickness than the vibrating region of the substrate, the strength of the substrate can be increased, and therefore, the resonator element superior in impact resistance or drop resistance can be obtained.

### APPLICATION EXAMPLE 11

This application example is directed to a resonator including the resonator element according to the application example described above, and a package adapted to house the resonator element.

According to this application example, by housing the resonator element in the package, a resonator high in reliability and quality can be obtained. For example, since the influence of a disturbance such as a temperature variation or a humidity variation, and the influence of contamination can be prevented, there is an advantage that the resonator superior in frequency reproducibility, frequency-temperature characteristic, CI-temperature characteristic, and frequency-aging characteristic can be obtained.

### APPLICATION EXAMPLE 12

This application example is directed to an oscillator including the resonator element according to the application example described above, and a circuit element electrically connected to the resonator element.

According to this application example, since the capacitance ratio γ of the resonator element is low, there is an advantage that an oscillator having a broad frequency variable range can be obtained.

### APPLICATION EXAMPLE 13

This application example is directed to an electronic apparatus including the resonator element according to the application example described above.

According to this application example, since the resonator element low in capacitance ratio γ is provided, there is an advantage that an electronic apparatus higher in performance can be obtained.

### APPLICATION EXAMPLE 14

This application example is directed to a mobile object including the resonator element according to the application example described above.

According to this application example, since the resonator element low in capacitance ratio γ is provided, there is an advantage that a mobile object higher in performance can be obtained.

### BRIEF DESCRIPTION OF THE DRAWINGS

Embodiments of the invention will be described with reference to the accompanying drawings, wherein like numbers reference like elements.

FIGS. 1A through 1C are diagrams showing a schematic configuration of a resonator element according to a first embodiment of the invention, wherein FIG. 1A is a schematic plan view, FIG. 1B is a schematic cross-sectional view along the P-P line, and FIG. 1C is a schematic cross-sectional view along the Q-Q line.

FIG. 2 is a diagram for explaining a relationship between an AT-cut quartz crystal substrate and a crystal axes.

FIGS. 3A and 3B are diagrams for explaining a vibration displacement distribution in the resonator element provided with excitation electrodes, wherein FIG. 3A is a schematic plan view, and FIG. 3B is a schematic cross-sectional view.

FIG. 4 is a table showing experimental production conditions and a measurement result of an AT-cut quartz crystal resonator element.

FIG. 5 is a diagram showing a ratio (γ/γ₀) of capacitance ratios of the resonator element with respect to a dimensional ratio (lx/Lx) of the excitation electrodes.

FIG. 6 is a diagram showing a ratio (γ/γ₀) of the capacitance ratios of the resonator element with respect to an area ratio (S2/S1) of the excitation electrodes.

FIG. 7 is a schematic plan view showing a schematic configuration of a resonator element according to Modified Example 1 of the invention.

FIGS. 8A and 8B are diagrams showing a schematic configuration of a resonator element according to Modified Example 2 of the invention, wherein FIG. 8A is a schematic plan view and FIG. 8B is a schematic cross-sectional view along the P-P line.

FIGS. 9A and 9B are diagrams showing a schematic configuration of a resonator element according to Modified Example 3 of the invention, wherein FIG. 9A is a schematic plan view and FIG. 9B is a schematic cross-sectional view along the P-P line.

FIGS. 10A and 10B are diagrams showing a schematic configuration of a resonator element according to Modified Example 4 of the invention, wherein FIG. 10A is a schematic plan view and FIG. 10B is a schematic cross-sectional view along the P-P line.

FIGS. 11A and 11B are diagrams showing a schematic configuration of a resonator element according to Modified Example 5 of the invention, wherein FIG. 11A is a schematic plan view and FIG. 11B is a schematic cross-sectional view along the R-R line.

FIG. 12 is a schematic plan view showing a schematic configuration of a resonator element according to a second embodiment of the invention.

FIG. 13 is a schematic plan view showing a schematic configuration of a resonator element according to a third embodiment of the invention.

FIG. 14 is a schematic plan view showing a schematic configuration of a resonator element according to a fourth embodiment of the invention.

FIGS. 15A and 15B are diagrams showing a schematic configuration of a resonator element according to an embodiment of the invention, wherein FIG. 15A is a schematic plan view and FIG. 15B is a schematic cross-sectional view.

FIGS. 16A and 16B are diagrams showing a schematic configuration of an oscillator according to an embodiment of the invention, wherein FIG. 16A is a schematic plan view and FIG. 16B is a schematic cross-sectional view.

FIG. 17 is a perspective view showing a configuration of a mobile type (or a laptop type) personal computer as an example of the electronic apparatus equipped with the resonator element according to an embodiment of the invention.

FIG. 18 is a perspective view showing a configuration of a cellular phone (including PHS) as an example of the electronic apparatus equipped with the resonator element according to an embodiment of the invention.

FIG. 19 is a perspective view showing a configuration of a digital still camera as an example of the electronic apparatus equipped with the resonator element according to an embodiment of the invention.

FIG. 20 is a perspective view schematically showing a vehicle as an example of a mobile object equipped with the resonator element according to an embodiment of the invention.

### DESCRIPTION OF EXEMPLARY EMBODIMENTS

Some embodiments of the invention will hereinafter be explained in detail based on the accompanying drawings. It should be noted that in the drawings described hereinafter, the dimensions and the ratios of the constituent elements are arbitrarily made different from those of the actual constituent elements in some cases in order to provide the constituent elements with recognizable sizes in the drawings.

### Resonator Element

### First Embodiment

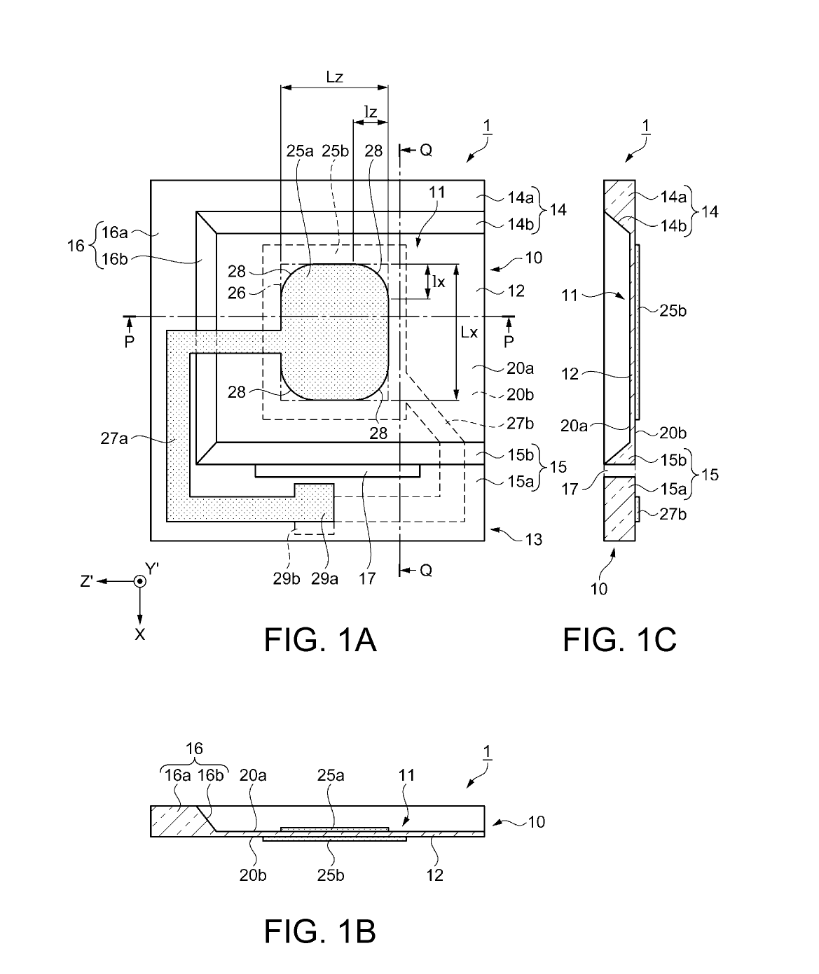

Firstly, as an example of a resonator element according to a first embodiment of the invention, there is cited a resonator element having a so-called inverted-mesa structure having a recessed section in the central portion of a substrate, and a schematic configuration of the resonator element will be explained with reference to FIGS. 1A through 1C.

FIGS. 1A through 1C are diagrams showing a schematic configuration of a resonator element according to the first embodiment of the invention, wherein FIG. 1A is a schematic plan view of the resonator element, FIG. 1B is a schematic cross-sectional view along the P-P line in FIG. 1A, and FIG. 1C is a schematic cross-sectional view along the Q-Q line in FIG. 1A.

The resonator element 1 is provided with a substrate 10 having a vibrating section 12, and a thick-wall section 13 continuously provided along an outer edge of the vibrating section 12 and larger in thickness than the vibrating section 12, a first excitation electrode 25a formed on a first principal surface 20a (a principal surface in the +Y′ direction) of the vibrating section 12, a second excitation electrode 25b formed on a second principal surface 20b (a principal surface in the −Y′ direction) of the vibrating section 12 so as to entirely overlap the first excitation electrode 25a in a planar view, lead electrodes 27a, 27b respectively extending from the first excitation electrode 25a and the second excitation electrode 26b, and pad electrodes 29a, 29b provided to the thick-wall section and respectively connected to the lead electrodes 27a, 27b.

The substrate 10 is provided with the vibrating section 12, which has a rectangular shape in a planar view, and is shaped like a thin-wall plate perpendicular to the Y′ axis with a constant thickness, the thick-wall section 13 composed of a first thick-wall section 14, a second thick-wall section 15, and a third thick-wall section 16 (also referred to as first, second, and third thick-wall sections 14, 15, and 16) integrated with each other along the three sides except one side of the outer edge of the vibrating section 12, and a slit 17 for preventing a mount stress caused when fixing and supporting the substrate 10 from being transmitted to the vibrating section 12.

It should be noted that a first thick-wall main body 14a, a second thick-wall main body 15a, and a third thick-wall main body 16a (also referred to as first, second, and third thick-wall main bodies 14a, 15a, and 16a) each denote a region having an even thickness in a direction parallel to the Y′ axis.

Further, in a first tilted (i.e., slanted) portion 14b, a second tilted portion 15b, and a third tilted portion 16b (also referred to as first, second, and third tilted portions 14b, 15b, and 16b), step regions respectively formed between the first, second, and third thick-wall main bodies 14a, 15a, and 16a and the vibrating section 12 each have a tilted surface.

One of the principal surfaces of the vibrating section 12 and one of the surfaces of each of the first, second, and third thick-wall sections 14, 15, and 16 are co-planar and aligned on the same plane, namely on the X-Z′ plane of the coordinate axes shown in FIG. 1A, the surface (the lower surface located on the −Y′ side in FIG. 1B) is called a flat surface, and the opposite surface (the upper surface located on the +Y′ side in FIG. 1B) having a recessed section 11 is called a recessed surface.

In the embodiment shown in FIGS. 1A through 1C, the first excitation electrode 25a is formed to have a shape obtained by removing (e.g., cutting or rounding) or omitting the four corners of a quadrangle, namely a shape which has sides having internal contact with a virtual quadrangle 26 formed of the length Lx parallel to the X-axis direction as the vibration direction of the thickness-shear vibration and the length Lz parallel to the Z′-axis direction as a direction intersecting with the vibration direction, and is obtained by omitting the four corners of the virtual quadrangle 26, in which the angle of each of the four corners is 90°, so as to have circular arc shapes. Specifically, a region of the vibrating section 12 sandwiched between the first excitation electrode 25a and the second excitation electrode 25b is located within a range of the virtual quadrangle 26, which has the angles of the four corners all equal to one another, and includes a pair of first sides parallel to the vibration direction of the thickness-shear vibration and a pair of second sides parallel to the direction perpendicular to the vibration direction in a planar view, and at the same time has contact with each of the pair of first sides and the pair of second sides. Therefore, an outer edge portion 28 on each of the four corners of the first excitation electrode 25a has a circular arc shape, and the first excitation electrode 25a is formed to have a roughly elliptical shape. This shape is also known as a rounded rectangle or, if the side lengths of the rectangle are equal, a rounded square. That is, a rectangle having rounded corners (e.g., fillets). Further, the areas of the cut shapes on the four corners of the virtual quadrangle 26 are preferably equal to one another. The second excitation electrode 25b is formed to have a quadrangular shape. Further, the first excitation electrode 25a and the second excitation electrode 25b are formed so as to respectively overlap the first principal surface 20a and the second principal surface 20b located in a roughly central portion of the vibrating section 12 in a planar view. It should be noted that the shape of each of the first excitation electrode 25a and the second excitation electrode 25b can also be a quadrangular shape, a rectangular shape, a circular arc shape, or an elliptical shape. It should be noted that in the present embodiment, although the explanation is presented assuming that the virtual quadrangle 26 has a quadrangular shape, the angle of the four corners of which is 90°, such as a rectangular shape (an oblong shape) or a square shape, it is possible to apply the invention even in the case in which the angle of each of the four corners is in a range of 87° through 93° taking the production tolerance of the first excitation electrode 25a or the second excitation electrode 25b into consideration.

The first excitation electrode 25a and the second excitation electrode 25b are different in size from each other, and the second excitation electrode 25b is larger than the first excitation electrode 25a. The region actually excited in the vibrating section 12 is the region sandwiched by the first excitation electrode 25a and the second excitation electrode 25b. Specifically, the region making a contribution to actually exciting the vibrating section 12 in the second excitation electrode 25b is a portion overlapping the first excitation electrode 25a in a planar view. In other words, the second excitation electrode 25b is composed of the electrode making a contribution to the excitation, and the electrode, which is integrated with the outer edge of the electrode making the contribution to the excitation, and does not make a contribution to the excitation.

It should be noted that regarding portions connected to the lead electrodes 27a, 27b, the shapes and the areas of the first excitation electrode 25a and the second excitation electrode 25b will be explained taking an extended line (an imaginary line) along the outer edge (the outer side) of the excitation electrode shape as a boundary.

It is preferable for the first excitation electrode 25a thus cut out to be symmetric about the center point of the first excitation electrode 25a, or to have the cut-out portions on the four corners equal in area to one another with respect to the virtual quadrangle 26. It should be noted that although it is preferable that the areas of the cut-out portions on the four corners of the virtual quadrangle 26 are equal to one another (roughly equivalent to one another) in the first excitation electrode 25a, even if the difference of about 10% occurs taking the production tolerance into consideration, it has been confirmed that the difference does not affect the actual vibration, and there is no problem which affects the advantage obtained by the present embodiment.

The lead electrode 27a extends from the first excitation electrode 25a formed on the recessed surface, passes through the tilted portion 16b and the third thick-wall main body 16a from the surface of the vibrating section 12, and is conductively connected to the pad electrode 29a formed on the recessed surface of the second thick-wall main body 15a. Further, the lead electrode 27b extends from the second excitation electrode 25b formed on the flat surface, and is conductively connected to the pad electrode 29b formed on the flat surface of the second thick-wall main body 15a via an end edge portion of the flat surface of the substrate 10.

The embodiment shown in FIG. 1A is an example of an extraction structure of the lead electrodes 27a, 27b, and the lead electrode 27a can pass through another thick-wall section. However, it is desirable that the lengths of the lead electrodes 27a, 27b are the shortest, and it is desirable to suppress increase in capacitance by giving consideration to preventing the lead electrodes 27a, 27b from intersecting with or overlapping each other across the substrate 10 in a planar view.

Further, the first excitation electrode 25a, the second excitation electrode 25b, the lead electrodes 27a, 27b, and the pad electrodes 29a, 29b are formed by, for example, depositing nickel (Ni) as a foundation layer, then depositing gold (Au) thereon as an upper layer in an overlapping manner using a vapor deposition device, a sputtering device, or the like, and then performing patterning using a photolithography process. It should be noted that it is also possible to use chromium (Cr) instead of nickel (Ni) of the foundation layer, and silver (Ag) or platinum (Pt) instead of gold (Au) of the upper layer as the electrode materials.

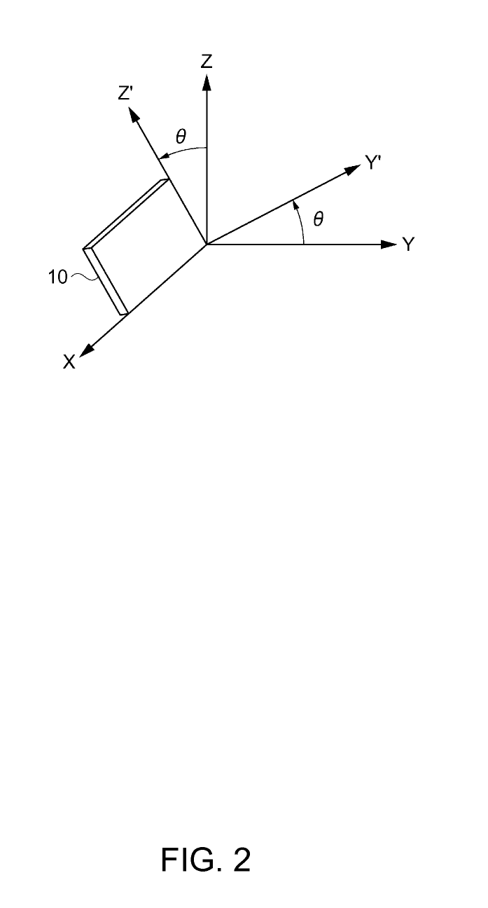

The substrate 10 of the vibrating element 1 according to the present embodiment will now be explained with reference to FIG. 2.

FIG. 2 is a diagram for explaining a relationship between an AT-cut quartz crystal substrate and crystal axes.

A piezoelectric material such as a quartz crystal belongs to a trigonal system, and has the crystal axes X, Y, and Z perpendicular to one another as shown in FIG. 2. The X axis, the Y axis, and the Z axis are called an electrical axis, a mechanical axis, and an optical axis, respectively. Further, among the quartz crystal substrates, a “rotated Y-cut quartz crystal substrate” carved out from the quartz crystal along a plane obtained by rotating the X-Z plane as much as an angle θ around the X axis is used as the substrate 10. For example, in the case of the AT-cut quartz crystal substrate, the angle θ is about 35°15′. It should be noted that the Y axis and the Z axis are also rotated as much as the angle θ around the X axis to thereby obtain the Y′ axis and the Z′ axis. Therefore, the AT-cut quartz crystal substrate has the crystal axes X, Y′, and Z′ perpendicular to one another. In the AT-cut quartz crystal substrate, the thickness direction is the Y′-axis direction, the principal surface is the X-Z′ plane (the plane including the X axis and the Z′ axis) perpendicular to the Y′ axis, and the thickness-shear vibration is excited as the principal vibration.

In other words, as shown in FIG. 2, assuming that an axis obtained by tilting the Z axis described above so that the +Z side thereof is rotated toward the −Y direction of the Y axis described above taking the X axis of the orthogonal coordinate system composed of the X axis (the electrical axis), the Y axis (the mechanical axis), and the Z axis (the optical axis) as the rotational axis is the Z′ axis, and an axis obtained by tilting the Y axis described above so that the +Y side thereof is rotated toward the +Z direction of the Z axis described above taking the X axis as the rotational axis is the Y′ axis, the substrate 10 is the “rotated Y-cut quartz crystal substrate” taking the plane including the X axis described above and the Z′ axis described above as a principal surface, and taking the direction along the Y′ axis described above as the thickness direction.

It should be noted that the substrate 10 according to the present embodiment is not limited to the AT-cut substrate with the angle θ of 35° 15′, but can widely be applied to, for example, a BT-cut substrate exciting the thickness-shear vibration.

Further, although the explanation is presented using the example of disposing the thick-wall section along the outer edge of the vibrating section 12, the invention is not limited thereto, but can widely be applied also to a substrate having the thick-wall section disposed along the entire outer edge of the vibrating section 12, and a plate-like substrate not provided with the thick-wall section.

It should be noted that the vibrating section 12 can be formed by, for example, forming a recessed section 11 on the first principal surface 20a of the quartz crystal substrate on the +Y′-axis side using a wet etching process.

Here, the resonator element 1 according to the present embodiment uses the AT-cut quartz crystal substrate, which has the cutting angle superior in temperature characteristics, as the substrate 10, and therefore has an advantage that the resonator element high in Q-value and superior in temperature characteristics can be obtained. Further, since accomplishments and experiences related to the photolithography technology and the etching technology can be utilized, mass production of the resonator element 1 small in characteristic variation becomes possible.

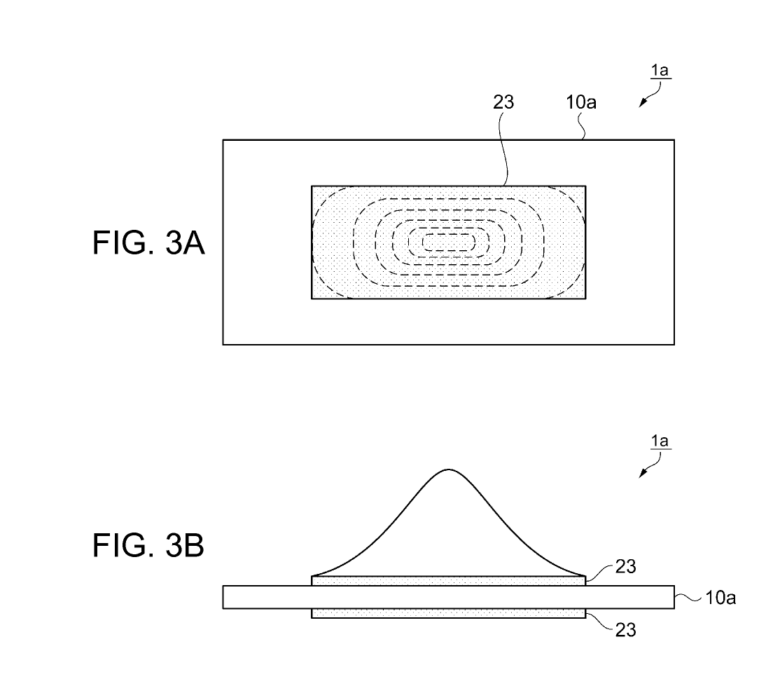

The vibration displacement of the resonator element 1a having a substrate 10a having a typical reed shape will now be explained with reference to FIGS. 3A and 3B.

FIGS. 3A and 3B are diagrams for explaining a vibration displacement distribution in the resonator element provided with the excitation electrodes, wherein FIG. 3A is a schematic plan view, and FIG. 3B is a schematic cross-sectional view of FIG. 3A.

FIGS. 3A and 3B show the result obtained by calculating the vibration displacement distribution in the thickness-shear vibration mode of the fundamental wave of the resonator element 1a having an excitation electrode 23 having a rectangular shape disposed on the substrate 10a using a finite element method. The drawing shows that the vibration displacement is very small in the four corner portions of the excitation electrode 23, and these portions do not make a contribution to the actual vibration. Here, the equivalent parallel capacitance C0 of the resonator element 1a is a capacitance between the obverse and reverse excitation electrodes, and therefore, depends on the area of the portions opposed to each other. However, the equivalent series capacitance C1 is a capacitance component in the actual vibrating region, and therefore, does not depend on the area of the opposed portions providing the area of the excitation electrode 23 is sufficiently large. Therefore, by removing or not providing a part of the excitation electrode 23, which does not make a contribution to the actual vibration, it is possible to decrease only the equivalent parallel capacitance C0 without affecting the equivalent series capacitance C1, and therefore, the resonator element 1a with the low capacitance ratio γ can be obtained.

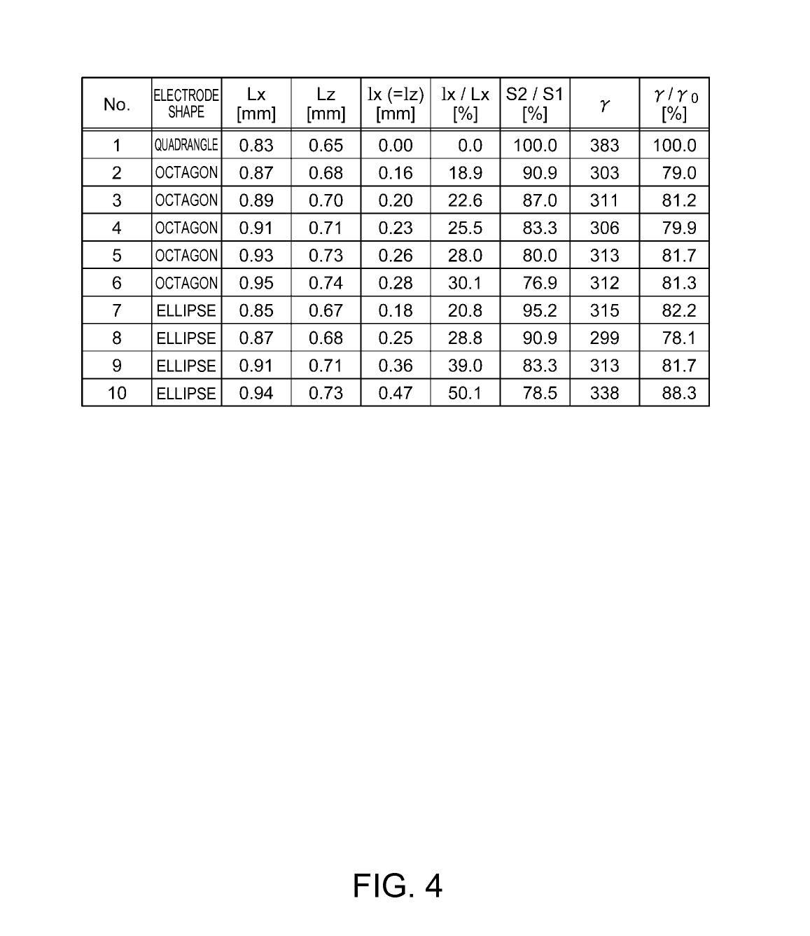

Experimental production conditions and a measurement result of the AT-cut quartz crystal resonator element (the resonator element 1) having the resonant frequency in a 100 MHz band experimentally manufactured as an example of the embodiment shown in FIGS. 1A through 1C will now be explained with reference to FIGS. 4 through 6.

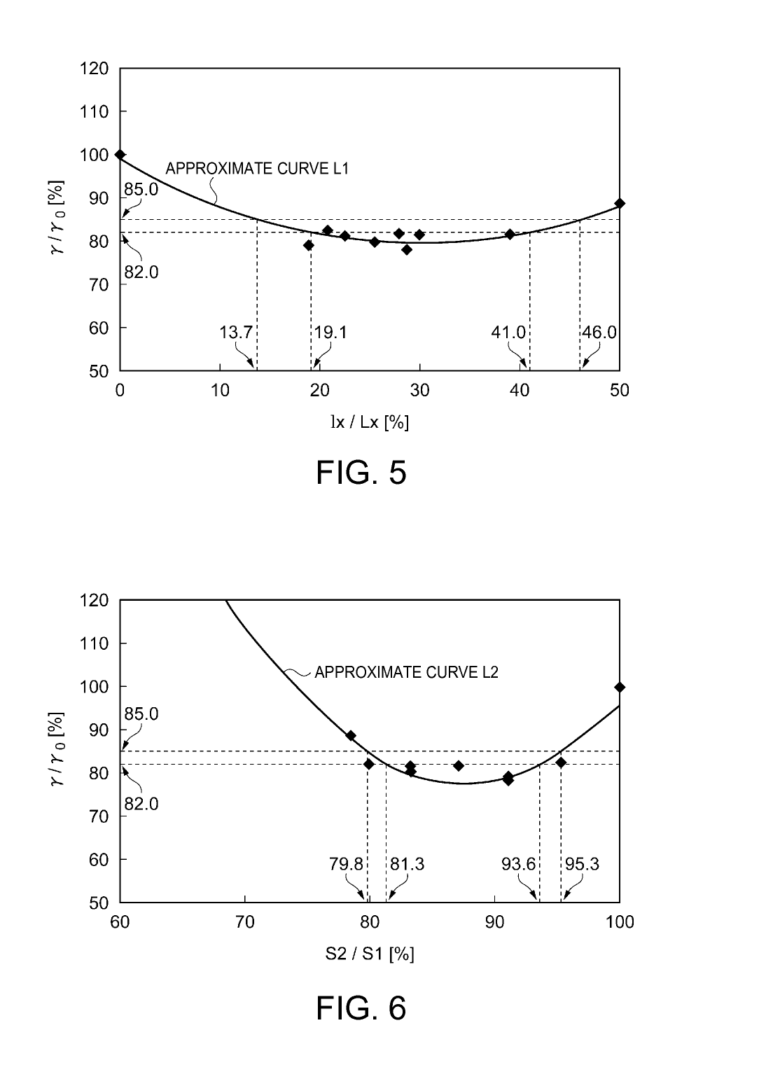

FIG. 4 is a table showing the experimental production conditions and the measurement result of the AT-cut quartz crystal resonator element thus experimentally manufactured. Further, FIG. 5 is a diagram obtained by plotting a ratio (γ/γ₀) between the capacitance ratios with respect to a dimensional ratio (lx/Lx) of the excitation electrodes of the AT-cut quartz crystal resonator element thus experimentally manufactured as a graph. FIG. 6 is a diagram obtained by plotting the ratio (γ/γ₀) between the capacitance ratios with respect to an area ratio (S2/S1) of the excitation electrodes of the AT-cut quartz crystal resonator element thus experimentally manufactured as a graph. Here, the ratio (γ/γ₀) between the capacitance ratios is hereinafter referred to as a standardized capacitance ratio.

The experimental production conditions of the AT-cut quartz crystal resonator element (the resonator element 1) having the resonant frequency in the 100 MHz band thus experimentally manufactured are three types of shapes of the area sandwiched between the first excitation electrode 25a and the second excitation electrode 25b shown in FIGS. 1A through 1C, namely a quadrangular shape, an octagon shape, and a roughly elliptical shape (rounded rectangle). Further, the area of the region sandwiched by the first excitation electrode 25a and the second excitation electrode 25b is represented by S2, the area of the virtual quadrangle 26 formed of the length Lx parallel to the X-axis direction and the length Lz parallel to the Z′-axis direction is represented by S1, and the area S2 is set to a constant value of 0.54 mm². Therefore, the dimensions lx, lz of the shape obtained by cutting the four corners of the virtual quadrangle 26 are adjusted so that the area S2 of the region sandwiched by the first excitation electrode 25a and the second excitation electrode 25b becomes 0.54 mm². It should be noted that in the present experimental production conditions, the dimensions lx, lz are set to fulfill a condition of lx=lz in performing the experimental production.

Further, as the measurement result, the capacitance ratio γ of the AT-cut quartz crystal resonator element (the resonator element 1) in each of the experimental production conditions is shown, and there is further shown a value standardized by the capacitance ratio γ (=γ₀) of the sample No. 1, in which the shape of the region sandwiched by the first excitation electrode 25a and the second excitation electrode 25b is a quadrangular shape. It should be noted that the reason that the sample No. 1 is used as the reference is that there is generally used the resonator element, in which the shape of the region sandwiched by the two excitation electrodes is a quadrangular shape.

In FIG. 5, the horizontal axis represents the dimensional ratio (lx/Lx), and the vertical axis represents the standardized capacitance ratio (γ/γ₀) with reference to the capacitance ratio γ (=γ₀) of the sample No. 1. An approximate curve L1 of the plotted data shows a convex-downward quadratic curve, and shows that the standardized capacitance ratio (γ/γ₀) has the minimum value in the vicinity of the dimensional ratio (lx/Lx) of about 30% and then tends to rise as the dimensional ratio (lx/Lx) increases.

According to FIG. 5, the range of the dimensional ratio (lx/Lx) in which the capacitance ratio can be reduced equal to or more than 15% with respect to the capacitance ratio γ of the sample No. 1 used generally, namely the standardized capacitance ratio (γ/γ₀) can be set to be equal to or lower than 85.0% is the range of 13.7%≦(lx/Lx)≦46.0%, and further, the capacitance ratio γ can be reduced equal to or more than 18%. In other words, the range of the dimensional ratio (lx/Lx) in which the standardized capacitance ratio (γ/γ₀) can be set to be equal to or lower than 82% is the range of 19.1%≦(lx/Lx)≦41.0%.

In FIG. 6, the horizontal axis represents the area ratio (S2/S1), and the vertical axis represents the standardized capacitance ratio (γ/γ₀) with reference to the capacitance ratio γ (=γ₀) of the sample No. 1. An approximate curve L2 of the plotted data shows a convex-downward quadratic curve, and shows that the standardized capacitance ratio (γ/γ₀) has the minimum value in the vicinity of the area ratio (S2/S1) of about 87% and then tends to rise as the area ratio (S2/S1) increases.

According to FIG. 6, the range of the area ratio (S2/S1) in which the capacitance ratio can be reduced equal to or more than 15% with respect to the capacitance ratio γ (=γ₀) of the sample No. 1 used generally, namely the standardized capacitance ratio (γ/γ₀) can be set to be equal to or lower than 85.0% is the range of 79.8%≦(lx/Lx)≦95.3%, and further, the capacitance ratio γ can be reduced equal to or more than 18%. In other words, the range of the area ratio (S2/S1) in which the standardized capacitance ratio (γ/γ₀) can be set to be equal to or lower than 82.0% is the range of 81.3%≦(S2/S1)≦93.6%.

Then, going back to FIGS. 1A through 1C, in the embodiment shown in FIG. 1A, the amount of the area of the first excitation electrode 25a on the recessed surface side (the first principal surface 20a side) is set to the level with which the first excitation electrode 25a fits into (is entirely inboard of) the outer edge of the outer shape of the second excitation electrode 25b on the flat surface side (the second principal surface 20b side). In other words, the first excitation electrode 25a is formed to have a shape smaller than that of the second excitation electrode 25b.

The thickness-shear vibration occurs only in the region in which the first excitation electrode 25a and the second excitation electrode 25b overlap each other in a planar view. Therefore, if the first excitation electrode 25a fits into the outer edge of the second excitation electrode 25b, the efficient confinement of the vibration energy of the principal vibration can be determined by the area and the thickness of the first excitation electrode 25a. Therefore, since the thickness of the electrode can be increased compared to the case in which the areas of the first excitation electrode 25a and the second excitation electrode 25b are equal to each other, it is possible to reduce the ohmic loss of the electrode films, and to reduce the deterioration of the CI value of the principal vibration.

Further, in the case of forming the first excitation electrode 25a and the second excitation electrode 25b using a metal mask method, since the area of the portions opposed to each other of the first excitation electrode 25a and the second excitation electrode 25b across the vibrating section 12 hardly varies even if some displacement occurs in forming the electrodes, there arises no variation of the equivalent series capacitance C1 or the equivalent parallel capacitance C0, and thus the resonator element 1 with a small variation in the capacitance ratio γ can be obtained.

Further, assuming that the length of the first excitation electrode 25a along the vibration direction of the thickness-shear vibration is Lx, and the length thereof along a direction intersecting with the vibration direction of the thickness-shear vibration is Lz, in the case of the AT-cut quartz crystal substrate, by setting the dimensional ratio (Lx/Lz) of the excitation electrode to 1.28, it is possible to efficiently confine the vibration energy of the principal vibration in the region of the excitation electrode on the grounds of the elastic constant due to the crystal anisotropy. Therefore, by setting the dimensional ratio (Lx/Lz) of the excitation electrode to the relationship of 1.25≦(Lx/Lz)≦1.31 taking the production tolerance into consideration, the vibration energy of the principal vibration can efficiently be confined, and therefore, the equivalent series capacitance C1 can further be increased, and thus, the resonator element 1 lower in capacitance ratio γ can be obtained.

Further, regarding the dimensions lx, lz of the shape of the virtual quadrangle 26 with the four corners cut out, since the dimensional ratio (Lx/Lz) is set to the relationship of 1.25≦(Lx/Lz)≦1.31, it is preferable to fulfill lx≧lz. By setting the dimensions to fulfill such a relationship, since the efficiency of the confinement of the vibration energy can be improved similarly to the dimensional ratio (Lx/Lz), the equivalent series capacitance C1 becomes large, and the capacitance ratio γ of the resonator element 1 can be made lower.

Further, assuming that the area of the vibrating section 12 of the substrate 10 is S0, by making the area ratio (S2/S0) between the area S0 of the substrate 10 and the area S2 of the region sandwiched by the first excitation electrode 25a and the second excitation electrode 25b fulfill the relationship of 4%≦(S2/S0)≦50%, the resonator element 1 stably vibrating and small in size can be obtained.

### Modified Example 1

Modified Example 1 of the resonator element 1 according to the first embodiment of the invention will now be explained.

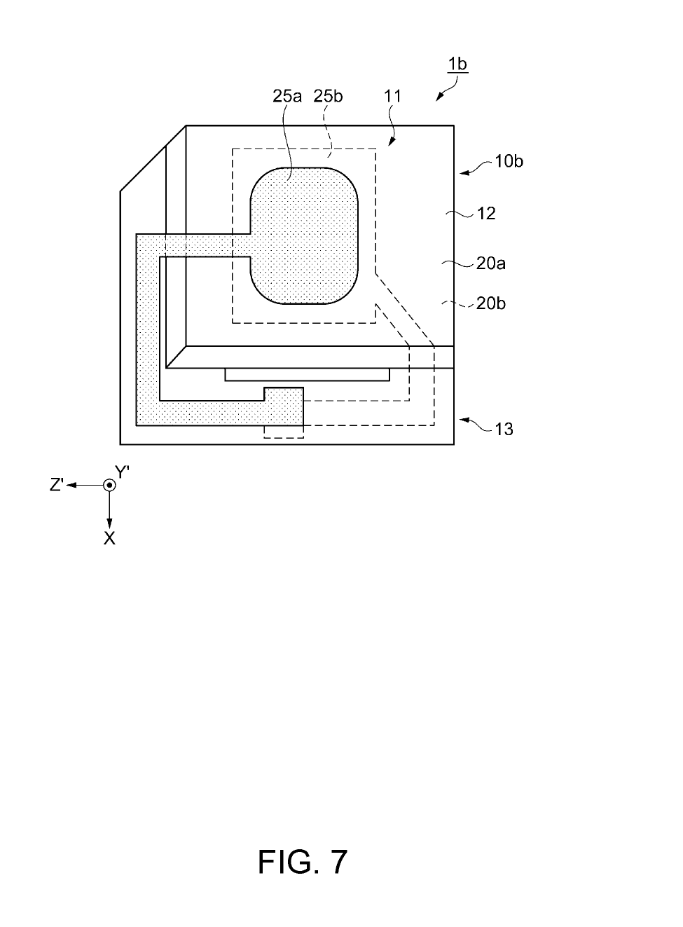

FIG. 7 is a schematic plan view showing a schematic configuration of a resonator element according to Modified Example 1 of the invention.

The resonator element 1b according to Modified Example 1 is different in the shape of the substrate 10b from the resonator element 1 explained in the description of the first embodiment. Compared to the substrate 10 of the resonator element 1 explained in the description of the first embodiment, the substrate 10b does not have a part of the thick-wall section 13 on the −X-axis side, and further has a shape obtained by obliquely cutting out a tip portion of the thick-wall section 13 on the +Z′-axis side.

By using such a substrate 10b, in the case of adopting a cantilever support structure for holding the thick-wall section 13 on the +X-axis side, the mass of the tip side (the −X-axis side) not supported can be reduced, and therefore, it is possible to reduce the variation in the vibration characteristics due to the external force such as acceleration (vibration), and obtain the resonator element 1b capable of exerting the stable vibration characteristics.

### Modified Example 2

Modified Example 2 of the resonator element 1 according to the first embodiment of the invention will now be explained.

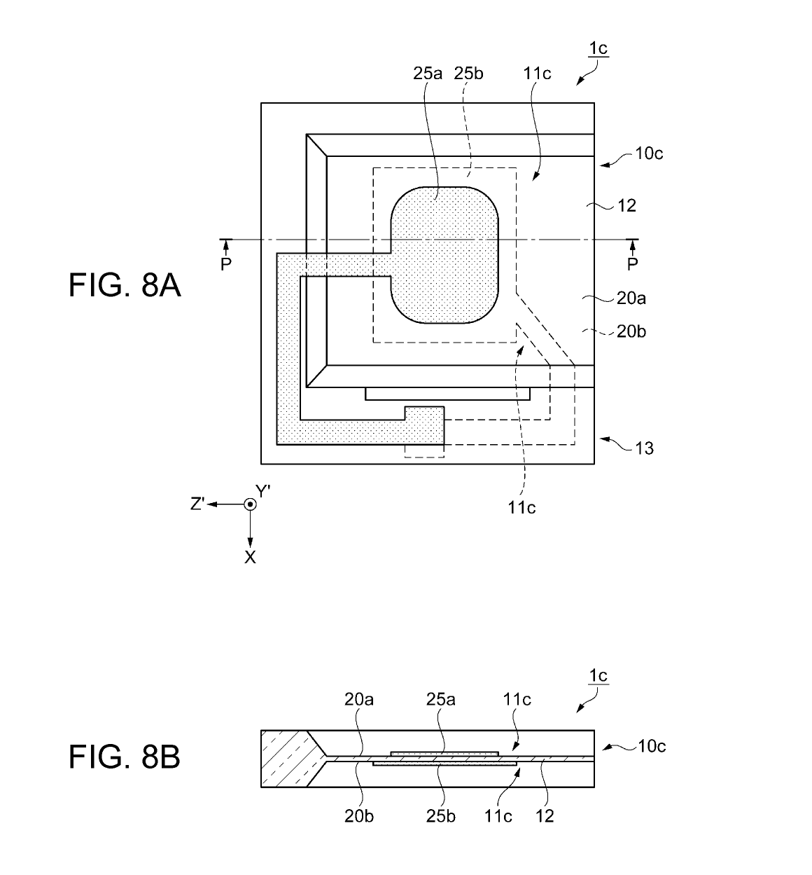

FIGS. 8A and 8B are diagrams showing a schematic configuration of the resonator element according to Modified Example 2 of the invention, wherein FIG. 8A is a schematic plan view and FIG. 8B is a schematic cross-sectional view along the P-P line in FIG. 8A.

The resonator element 1c according to Modified Example 2 is different in the shape of the substrate 10c from the resonator element 1 explained in the description of the first embodiment. Compared to the substrate 10 of the resonator element 1 explained in the description of the first embodiment, the substrate 10c is provided with the recessed sections 11c respectively formed on the first principal surface 20a and the second principal surface 20b.

By using such a substrate 10c, the processing time for forming the recessed sections 11c using the wet etching process is cut in half by performing the wet etching process from both of the principal surfaces (the first principal surface 20a and the second principal surface 20b), which is effective for reducing the manufacturing cost. Therefore, the resonator element 1c low in capacitance ratio γ can be obtained at low cost.

### Modified Example 3

Modified Example 3 of the resonator element 1 according to the first embodiment of the invention will now be explained.

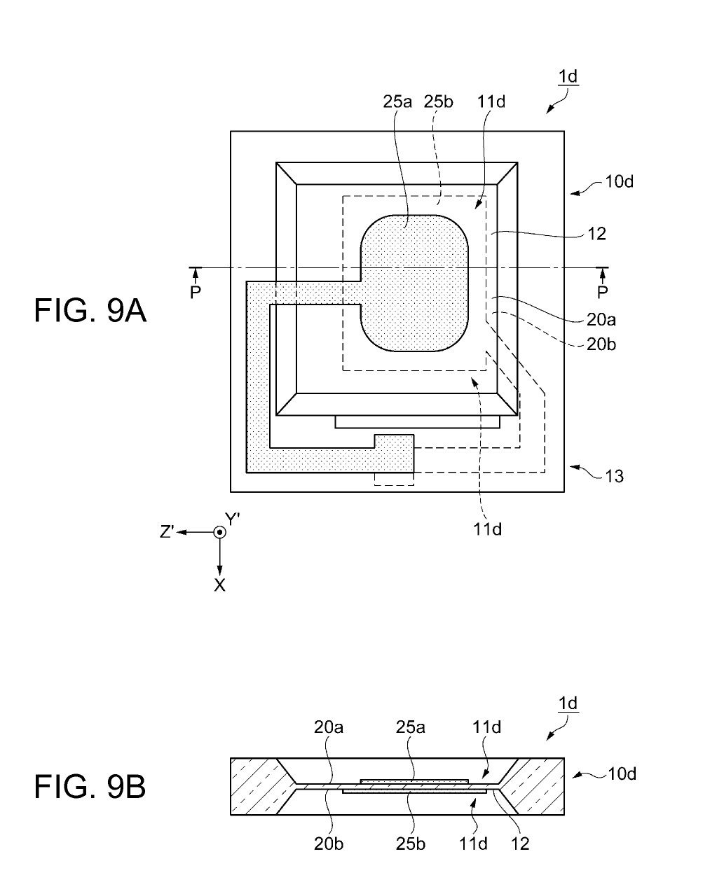

FIGS. 9A and 9B are diagrams showing a schematic configuration of the resonator element according to Modified Example 3 of the invention, wherein FIG. 9A is a schematic plan view and FIG. 9B is a schematic cross-sectional view along the P-P line in FIG. 9A.

The resonator element 1d according to Modified Example 3 is different in the shape of the substrate 10d from the resonator element 1 explained in the description of the first embodiment. Compared to the substrate 10 of the resonator element 1 explained in the description of the first embodiment, an integrated thick-wall section 13 is formed on the four sides of the vibrating section 12 having a roughly rectangular shape of the substrate 10d, and the substrate 10d is provided with the recessed sections 11d respectively formed on the first principal surface 20a and the second principal surface 20b.

By using such a substrate 10d, the periphery of the vibrating section 12 is reinforced by the thick-wall section 13. Therefore, it is possible to obtain the resonator element 1d increased in mechanical strength, superior in resistance against an impact such as a drop impact, and low in capacitance ratio γ.

### Modified Example 4

Modified Example 4 of the resonator element 1 according to the first embodiment of the invention will now be explained.

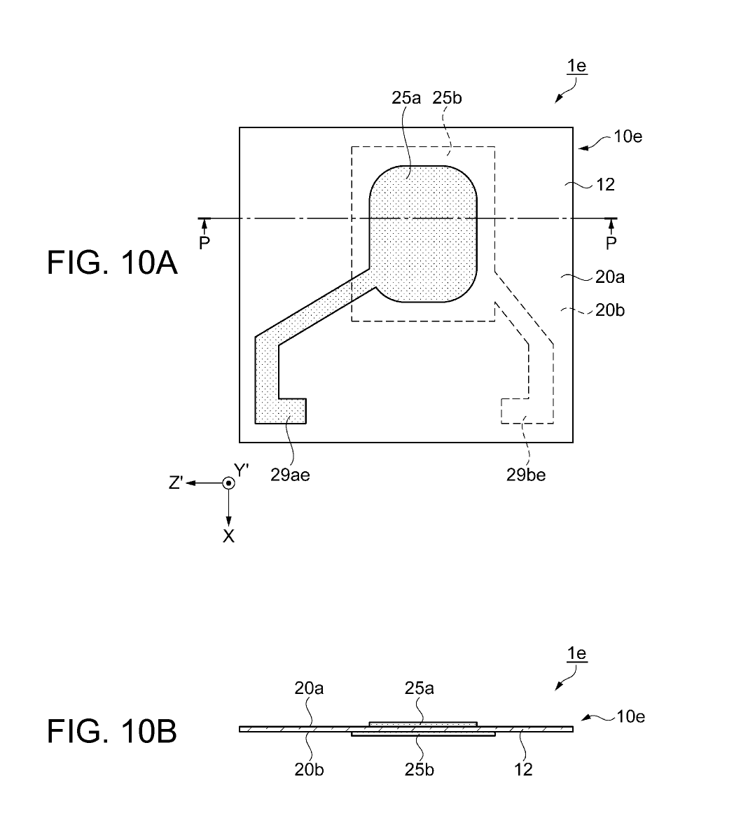

FIGS. 10A and 10B are diagrams showing a schematic configuration of the resonator element according to Modified Example 4 of the invention, wherein FIG. 10A is a schematic plan view and FIG. 10B is a schematic cross-sectional view along the P-P line in FIG. 10A.

The resonator element 1e according to Modified Example 4 is different in the shape of the substrate 10e from the resonator element 1 explained in the description of the first embodiment. Compared to the substrate 10 of the resonator element 1 explained in the description of the first embodiment, the substrate 10e does not have the thick-wall section on the periphery of the vibrating section 12, and the thickness of the entire substrate 10e is roughly even.

By using such a substrate 10e, since the processing of the substrate 10e only requires to perform polishing processing from the both surfaces, the recessed section forming process using the wet etching process is not required, and thus, the manufacturing cost of the substrate 10e can be reduced. Therefore, the resonator element 1e low in capacitance ratio γ can be obtained at low cost.

### Modified Example 5

Modified Example 5 of the resonator element 1 according to the first embodiment of the invention will now be explained.

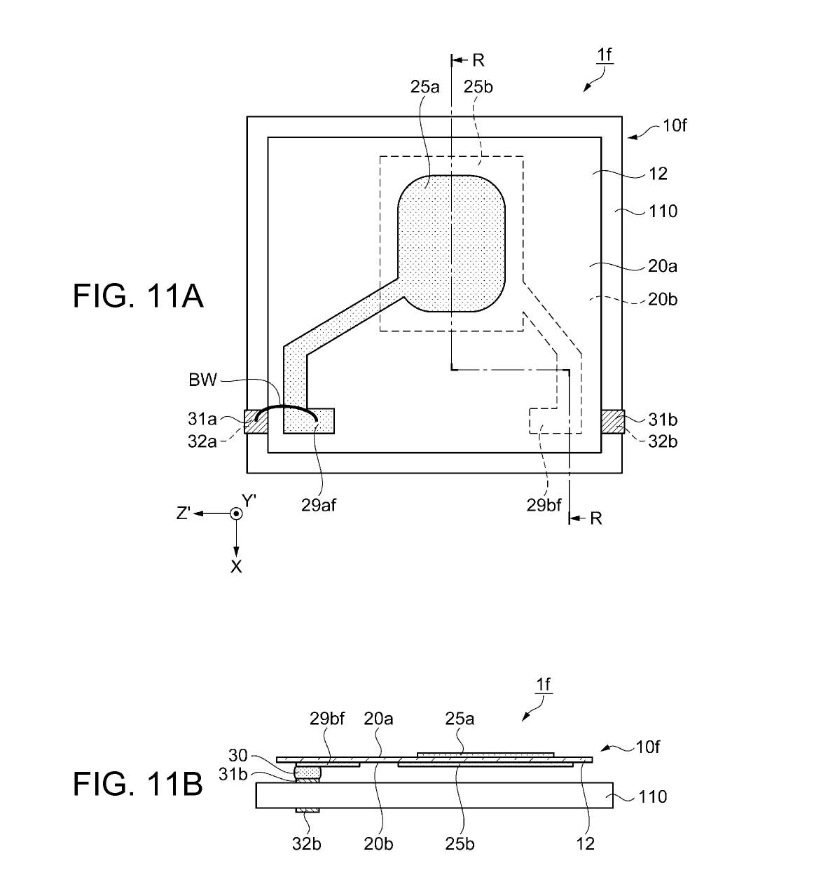

FIGS. 11A and 11B are diagrams showing a schematic configuration of the resonator element according to Modified Example 5 of the invention, wherein FIG. 11A is a schematic plan view and FIG. 11B is a schematic cross-sectional view along the R-R line in FIG. 11A.

The resonator element 1f according to Modified Example 5 is different in the shape of the substrate 10f from the resonator element 1 explained in the description of the first embodiment, and is further provided with a substrate 110 for holding the substrate 10f. Compared to the substrate 10 of the resonator element 1 explained in the description of the first embodiment, the substrate 10f does not have the thick-wall section on the periphery of the vibrating section 12, and the thickness of the entire substrate 10f is roughly even.

On both principal surfaces of the substrate 110 for holding the substrate 10f, there are formed pad electrodes 31a, 31b, 32a, and 32b, and the pad electrode 31a and the pad electrode 32a are electrically connected to each other via a side electrode (not shown) formed on a side surface of the substrate 110, and the pad electrode 31b and the pad electrode 32b are electrically connected to each other via a side electrode (not shown) formed on a side surface of the substrate 110.

The pad electrode 29bf of the substrate 10f and the pad electrode 31b of the substrate 110 are bonded to each other with an electrically-conductive adhesive 30, and are thus electrically connected to each other. Further, the rear surface of the pad electrode 29af of the substrate 10f and the principal surface of the substrate 110 on which the pad electrode 31a is formed are bonded to each other via a bonding member (not shown) such as an electrically-conductive adhesive 30. Further, the pad electrode 29af of the substrate 10f and the pad electrode 31a of the substrate 110 are electrically connected to each other via a bonding wire BW. It should be noted that the pad electrodes 32a, 32b formed on the rear surface of the substrate 110 are bonded to internal terminals of a package used for mounting, and are thus electrically connected thereto.

By using the substrate 10f mounted on such a substrate 110, the mechanical strength can be increased compared to mounting of the substrate 10f alone. Therefore, it is possible to obtain the resonator element if superior in resistance against an impact such as a drop impact, and low in capacitance ratio γ.

### Second Embodiment

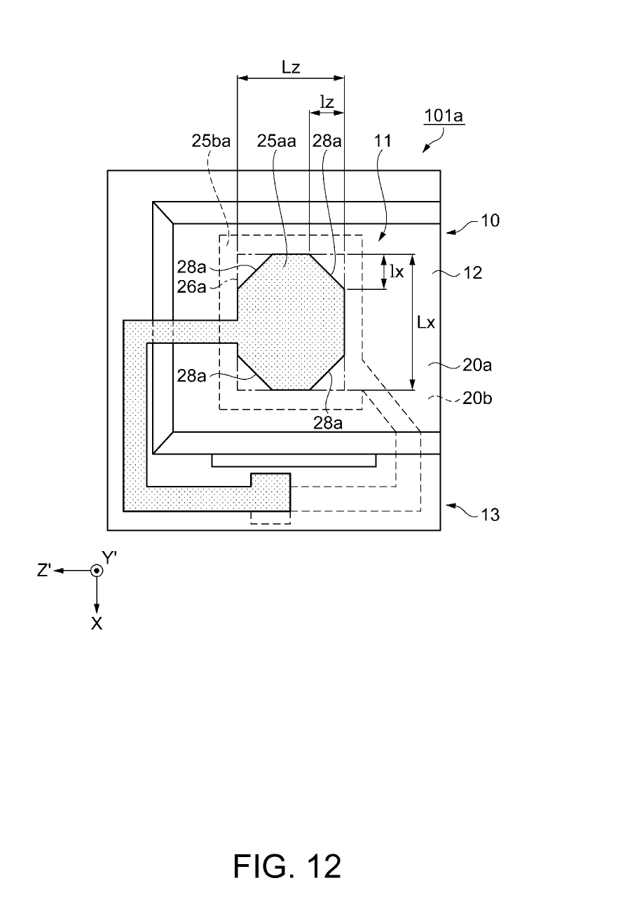

A resonator element 101a according to a second embodiment of the invention will now be explained with reference to FIG. 12.

FIG. 12 is a schematic plan view showing a schematic configuration of the resonator element according to the second embodiment of the invention.

The resonator element 101a according to the second embodiment is different from the resonator element 1 explained in the description of the first embodiment in the point that the shape of the outer edge portion 28a of the first excitation electrode 25aa having contact with the virtual quadrangle 26a is not a circle, but is a linear side. In other words, the first electrode 25aa is shaped as a truncated rectangle (including a truncated square) with straight cut corners (e.g., chamfers). As a result, the first electrode 25aa has an octagonal shape. The depth of the corner cuts can be shallow (shallow truncation) to provide the truncated rectangle or deeper to provide a truncated square (uniform truncation).

By adopting such a configuration, it is possible to remove an unwanted capacitance caused in a region making no contribution to the thickness-shear vibration, efficiently confine the vibration energy of the thickness-shear vibration, and increase the equivalent series capacitance C1, and at the same time decrease the equivalent parallel capacitance C0 determined by the area of the excitation electrode in the region sandwiched by the first excitation electrode 25aa and the second excitation electrode 25ba. Therefore, the resonator element 101a low in capacitance ratio γ can be obtained.

### Third Embodiment

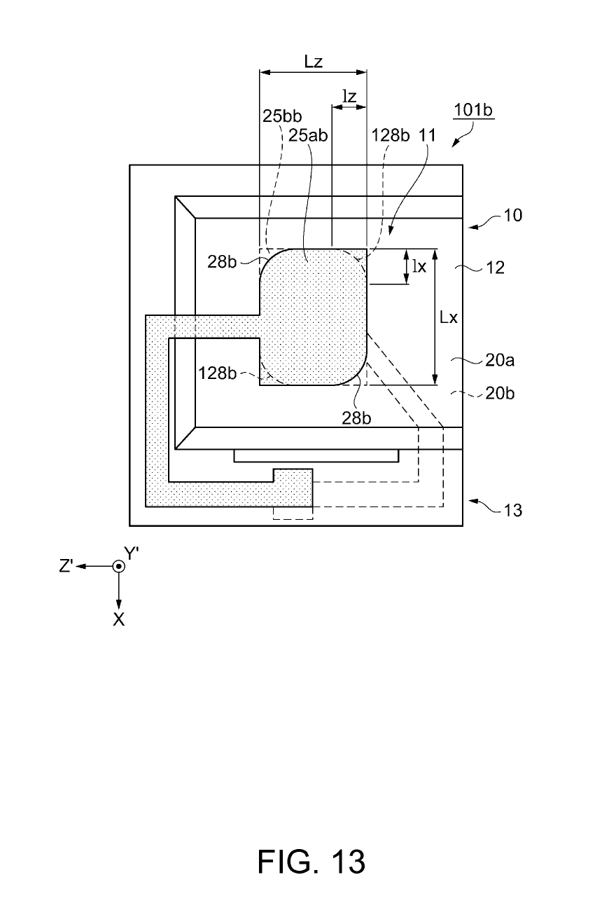

A resonator element 101b according to a third embodiment of the invention will now be explained with reference to FIG. 13.

FIG. 13 is a schematic plan view showing a schematic configuration of the resonator element according to the third embodiment of the invention.

The resonator element 101b according to the third embodiment is different from the resonator element 1 explained in the description of the first embodiment in the shapes of the first excitation electrode 25ab and the second excitation electrode 25bb.

In the outer shape of the first excitation electrode 25ab, the outer edge portions 28b on two corners on a diagonal of a quadrangle, namely on the corner located on the −X-axis side and the +Z′-axis side and the corner located on the +X-axis side and the −Z′-axis side, each have a circular arc shape. Further, in the outer shape of the second excitation electrode 25bb, the outer edge portions 128b on two corners on a diagonal of the quadrangle, namely on the corner located on the −X-axis side and the −Z′-axis side and the corner located on the +X-axis side and the +Z′-axis side, each have a circular arc shape.

By adopting such a configuration, the shape of the region sandwiched by the first excitation electrode 25ab and the second excitation electrode 25bb becomes equivalent to that in the resonator element 1 explained in the description of the first embodiment. Therefore, it is possible to remove an unwanted capacitance caused in a region making no contribution to the thickness-shear vibration, efficiently confine the vibration energy of the thickness-shear vibration, and increase the equivalent series capacitance C1, and at the same time decrease the equivalent parallel capacitance C0 determined by the area of the excitation electrode. Therefore, the resonator element 101b low in capacitance ratio γ can be obtained.

### Fourth Embodiment

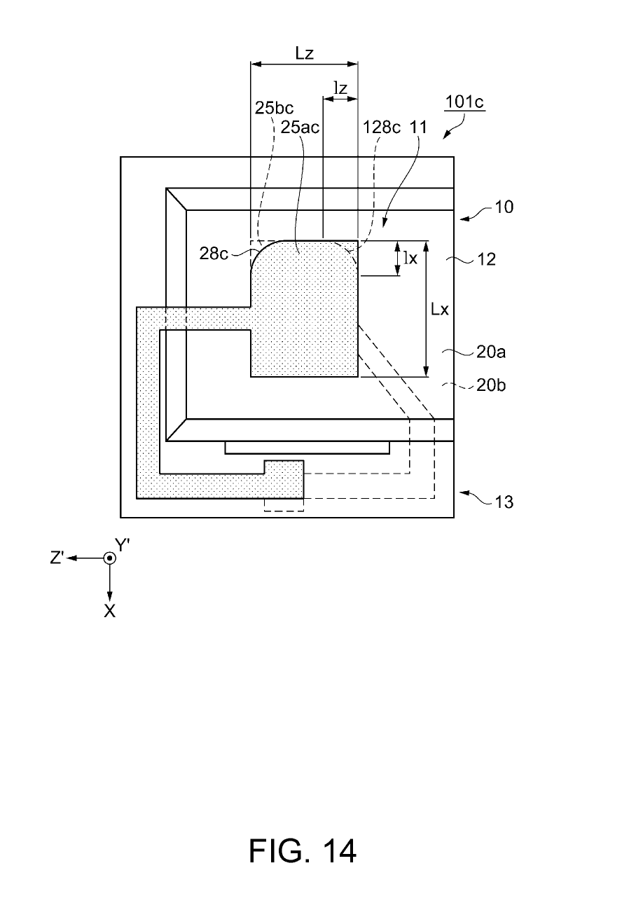

A resonator element 101c according to a fourth embodiment of the invention will now be explained with reference to FIG. 14.

FIG. 14 is a schematic plan view showing a schematic configuration of the resonator element according to the fourth embodiment of the invention.

The resonator element 101c according to the fourth embodiment is different from the resonator element 1 explained in the description of the first embodiment in the shapes of the first excitation electrode 25ac and the second excitation electrode 25bc.

In the outer shape of the first excitation electrode 25ac, the outer edge portion 28c on one corner of the quadrangle, namely the corner located on the −X-axis side and the +Z′-axis side, has a circular arc shape. Further, in the outer shape of the second excitation electrode 25bc, the outer edge portion 128c on one corner of the quadrangle and not overlapping the outer edge portions 28c in a planar view, namely the corner located on the −X-axis side and the −Z′-axis side, has a circular arc shape.

By adopting such a configuration, it is possible to remove an unwanted capacitance caused in a region making no contribution to the thickness-shear vibration, efficiently confine the vibration energy of the thickness-shear vibration, and increase the equivalent series capacitance C1, and at the same time decrease the equivalent parallel capacitance C0 determined by the area of the excitation electrode in the region sandwiched by the first excitation electrode 25ac and the second excitation electrode 25bc. Therefore, the resonator element 101c low in capacitance ratio γ can be obtained.

### Resonator

The resonator 2 (the resonator according to the invention) to which the resonator element 1 described above is applied will now be explained.

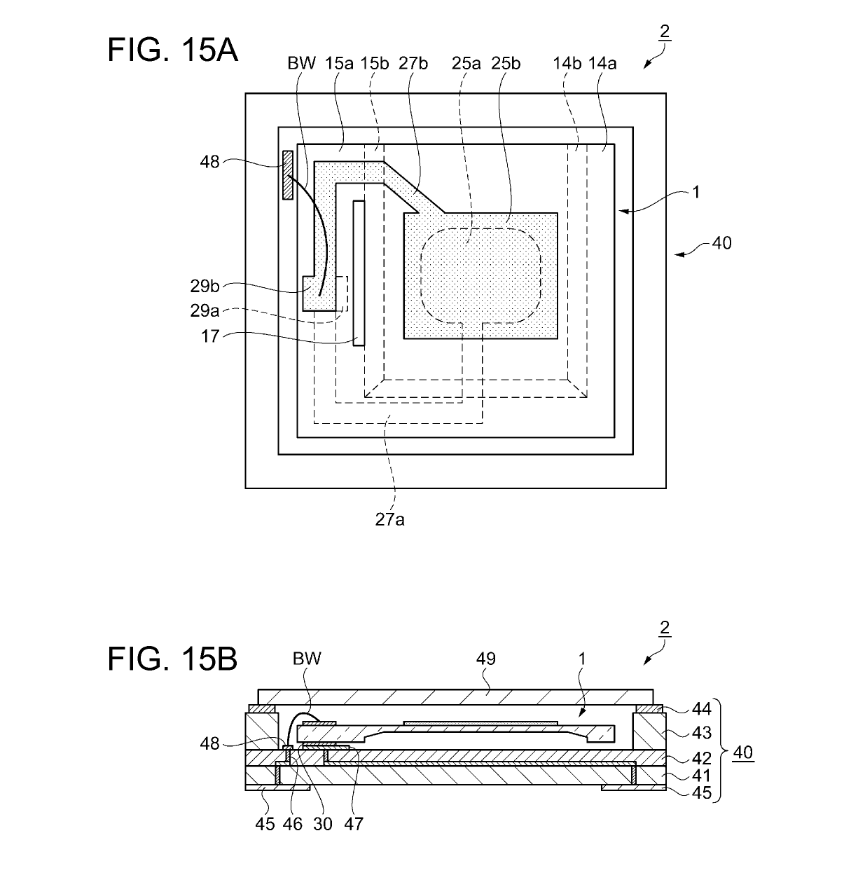

FIGS. 15A and 15B are diagrams showing a schematic configuration of the resonator according to an embodiment of the invention, wherein FIG. 15A is a schematic plan view, and FIG. 15B is a schematic cross-sectional view of FIG. 15A. It should be noted that in FIG. 15A, for the sake of convenience of explanation of an internal configuration of the resonator 2, there is shown a state with a lid member 49 removed.

The resonator 2 according to the present embodiment is composed of the resonator element 1, a package main body 40 formed to have a rectangular box shape in order to house the resonator element 1, and the lid member 49 made of metal, ceramic, glass, or the like.

As shown in FIGS. 15A and 15B, the package main body 40 is formed by stacking a first substrate 41, a second substrate 42, a third substrate 43, a seal ring 44, and mounting terminals 45 on one another. The mounting terminals 45 are formed on an exterior bottom surface of the first substrate 41. The third substrate 43 is a ring-like member with the central portion removed, and on the upper peripheral edge of the third substrate 43, there is formed the seal ring 44 made of, for example, Kovar™.

The third substrate 43 and the second substrate 42 constitute a recessed section (a cavity) for housing the resonator element 1. At predetermined positions on the upper surface of the second substrate 42, there is disposed a plurality of element mounting pads 47 having electrical conduction with the mounting terminals 45 with conductors 46. The element mounting pads 47 are arranged so as to correspond to the pad electrode 29a provided to the second thick-wall main body 15a when mounting the resonator element 1.

When fixing the resonator element 1, firstly, the resonator element 1 is flipped (reversed), then the pad electrode 29a is mounted on the element mounting pads 47 coated with an electrically conductive adhesive 30, and then load is applied thereon. As the electrically conductive adhesive 30, a polyimide adhesive with little outgas is used taking aging into consideration.

Then, in order to cure the thermosetting electrically-conductive adhesive 30 of the resonator element 1 mounted on the package main body 40, the package main body 40 and the resonator element 1 are put into a high-temperature oven at predetermined temperature for a predetermined time period. After curing the electrically-conductive adhesive 30, the pad electrode 29b having appeared on the upper surface by flipping and an electrode terminal 48 of the package main body 40 are conductively connected to each other with a bonding wire BW. As shown in FIG. 15B, since the resonator element 1 is supported by and fixed to the package main body 40 at one place (one point), it becomes possible to reduce the level of the stress generated by supporting and fixing the resonator element 1.

After performing an annealing treatment thereon, a frequency adjustment is performed by adding or removing amass to or from the second excitation electrode 25b. Subsequently, the lid member 49 is mounted on the seal ring 44 formed on the upper surface of the package main body 40, and then sealing is performed by seam welding the lid member 49 in a reduced-pressure atmosphere, or a nitrogen gas atmosphere to thereby complete the resonator 2. Alternatively, there can also be adopted a method of mounting the lid member 49 on a low-melting-point glass applied on the upper surface of the third substrate 43 of the package main body 40, and then melting the low-melting-point glass to thereby make the lid member 49 adhere. Also in this case, the cavity of the package is kept in the reduced-pressure atmosphere or filled with an inert gas such as a nitrogen gas to thereby complete the resonator 2.

It is also possible to configure the resonator element 1 having the pad electrodes 29a, 29b formed apart from each other in the Z′-axis direction as shown in FIG. 11A. Further, it is also possible to configure the resonator element 1 having the pad electrodes 29a, 29b formed on the same surface with a certain interval. In this case, the resonator element 1 has a structure of achieving the conduction, support, and fixation by applying the electrically-conductive adhesive 30 at two places (two points). Although the structure is suitable for height reduction, the mounting stress caused by the electrically-conductive adhesive 30 might be a little bit stronger.

Although the example of using the laminate substrate as the package main body 40 is hereinabove explained as the resonator 2 according to the embodiment, it is also possible to configure the resonator using a single layer ceramic substrate as the package main body 40, and using a cap, on which drawing has been performed, as the lid member.

As shown in FIGS. 15A and 15B, since the stress caused by the electrically-conductive adhesive 30 can be reduced by supporting the resonator element 1 at one point, and disposing the slit 17 between the thick-wall section 13 and the vibrating section 12, there is an advantage that the resonator 2 superior in frequency reproducibility, frequency-temperature characteristic, CI-temperature characteristic, and frequency-aging characteristic can be obtained.

### Oscillator

The oscillator 3 (the oscillator according to the invention) to which the resonator element 1 described above is applied will now be explained.

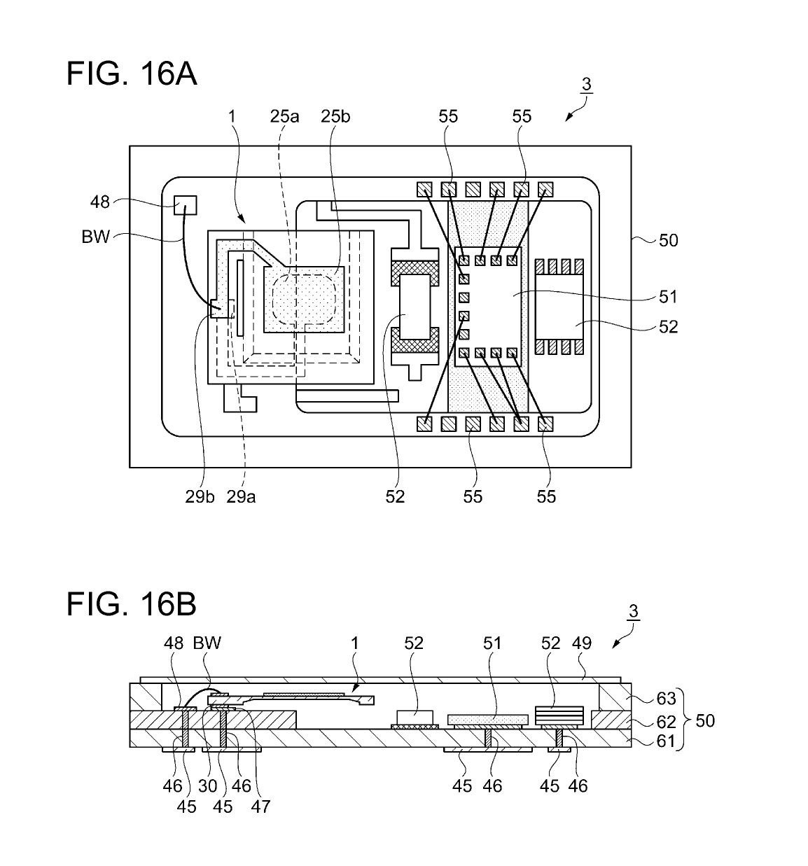

FIGS. 16A and 16B are diagrams showing a schematic configuration of the oscillator according to an embodiment of the invention, wherein FIG. 16A is a schematic plan view, and FIG. 16B is a schematic cross-sectional view of FIG. 16A. It should be noted that in FIG. 16A, for the sake of convenience of explanation of an internal configuration of the oscillator 3, there is shown a state with a lid member 49 removed.

The oscillator 3 according to the present embodiment is provided with a package main body 50, the lid member 49, the resonator element 1, an IC component 51 equipped with the oscillator circuit for exciting the resonator element 1, and at least one of electronic components 52 including a variable capacitance element, the capacitance of which varies in accordance with an applied voltage, a thermistor, the resistance of which varies in accordance with the temperature, an inductor, and so on.

As shown in FIGS. 16A and 16B, the package main body 50 is formed by stacking a first substrate 61, a second substrate 62, and a third substrate 63 on one another. The mounting terminals 45 are formed on an exterior bottom surface of the first substrate 61. The second substrate 62 and the third substrate 63 are each formed of a ring-like member with a central portion removed.

The first substrate 61, the second substrate 62, and the third substrate 63 constitute a recessed section (a cavity) for housing the resonator element 1, the IC component 51, the electronic component 52, and so on. At predetermined positions on the upper surface of the second substrate 62, there is disposed a plurality of element mounting pads 47 having electrical conduction with the mounting terminals 45 with conductors 46. The element mounting pads 47 are arranged so as to correspond to the pad electrode 29a provided to the second thick-wall main body 15a when mounting the resonator element 1.

The pad electrode 29a of the resonator element 1 flipped is mounted on the element mounting pads 47 of the package main body 50 coated with the electrically-conductive adhesive (polyimide series) 30 to thereby achieve conduction between the pad electrode 29a and the element mounting pads 47. The pad electrode 29a having appeared on the upper surface by flipping and the electrode terminal 48 of the package main body 50 are connected to each other with the bonding wire BW to thereby achieve conduction with one of the electrode terminals 55 of the IC component 51 via a conductor (not shown) formed between the substrates of the package main body 50. The IC component 51 is fixed at a predetermined position of the package main body 50, and then, the terminals of the IC component 51 and the electrode terminals 55 of the package main body 50 are connected to each other with the bonding wires BW. Further, the electronic component 52 is mounted at a predetermined position of the package main body 50, and is connected to the conductors 46 with metal bumps and so on. The package main body 50 is kept in a reduced-pressure atmosphere or filled with an inert gas such as a nitrogen gas, and then the package main body 50 is sealed with the lid member 49 to thereby complete the oscillator 3.

The method of connecting the pad electrode 29b and the electrode terminal 48 of the package main body 50 to each other with the bonding wire BW reduces the mounting stress caused by the electrically conductive adhesive 30 since the resonator element 1 is supported by one region (at one point). Further, since the resonator element 1 is flipped to set the second excitation electrode 25b with a larger size to the upper side in housing the resonator element 1 in the package main body 50, the frequency adjustment of the oscillator 3 becomes easy.

A voltage-controlled oscillator as the oscillator 3 equipped with the resonator element 1 according to the present embodiment will now be explained in detail.

In general, the voltage-controlled oscillator is composed of the resonator element 1, an oscillator circuit section such as the IC component 51, and a control voltage terminal including a variable-capacitance diode as an electronic component 52, and so on, and has a frequency variable range, in which the oscillation frequency of the resonator element 1 is varied in accordance with the control voltage, as an important specification. Since the frequency variable range is the sum of the absolute frequency variable range (APR) necessary for transmission communication equipment and the frequency tolerance (a frequency variation due to the frequency tolerance, frequency-temperature characteristic, and the power supply voltage, a frequency variation due to the load, a frequency variation due to reflow, and a frequency variation due to aging), the voltage controlled oscillator compensates the frequency variation amount due to the variation of the external environment of the oscillator and the oscillator circuit condition by itself. Therefore, the fact that the broad frequency variable range can be provided is very important for improving the production yield of the voltage-controlled oscillator since the frequency tolerance due to the manufacture and the design can be eased.

Here, the frequency variable sensitivity S of the voltage-controlled oscillator is expressed as the formula (1) described below.

S=−ΔCL/(2×γ×C0×(1+CL/C0)²) (1)

Here, ΔCL denotes a load capacitance variation, γ denotes the capacitance ratio (C0/C1), C0 denotes an equivalent parallel capacitance, and CL denotes a load capacitance.

According to the formula (1), if the load capacitance CL constituted by the oscillator circuit is constant, the frequency variable sensitivity S is determined by the equivalent parallel capacitance C0 of the resonator element 1 and the capacitance ratio γ, and in particular, the influence of the capacitance ratio γ is significant. Therefore, by using the resonator element 1 low in capacitance ratio γ, the frequency variable sensitivity S of the voltage-controlled oscillator can be increased, and thus, the voltage-controlled oscillator large in frequency variable range can be obtained.

In other words, as an advantage obtained by mounting the resonator element 1 according to the present embodiment arranged to have the low capacitance ratio γ on the voltage-controlled oscillator, the frequency variable range, which cannot be obtained when mounting the resonator element having the rectangular excitation electrode, can be set to a desired value at an arbitrary frequency.

For example, in the case in which there is a regulation that the frequency variable range is equal to or larger than ±100 ppm at the variable control voltage Vc=1.65V±1.65V, it is possible to realize the performance that the frequency variable range is ±115 ppm (Typ.) by improving the capacitance ratio γ, which can be realized by the resonator element 1 according to the present embodiment, to a low value although the frequency variable range is ±95 ppm (Typ.) in the case of the resonator element having the rectangular excitation electrode.

Further, as a method of controlling the frequency variable range, use of an extension coil is cited. By using the extension coil with a high value, the frequency variable range can be increased. However, in this case, there is a disadvantage that the phase noise becomes relatively worse due to the noise generated from the extension coil.

In contrast, if the capacitance ratio γ is low as in the case of the resonator element 1 according to the present embodiment, the frequency variable range can be increased. Therefore, since it is not necessary to use the extension coil with the high value, the deterioration of the phase noise can be reduced.

For example, in the case of realizing the frequency variable range of ±100 ppm at the variable control voltage Vc=1.65V±1.65V at the frequency of 122.88 MHz, by using the resonator element 1 low in capacitance ratio γ, the noise generated from the extension coil can be reduced by decreasing the extension coil value from, for example, 150 nH to 120 nH. Therefore, the phase noise can be improved.

By configuring the oscillator 3 as shown in FIGS. 16A and 16B, since the high-frequency resonator element 1 excited with the fundamental wave is used, the capacitance ratio is low, and the frequency variable range can be broadened. Further, there is obtained an advantage that a voltage-controlled oscillator with a preferable S/N ratio can be obtained.

By installing the resonator element 1 low in capacitance ratio γ according to the present embodiment in the voltage-controlled oscillator of an optical transmission device dealing with higher capacitance or higher speed of the optical transmission in a variety of types of networks, it becomes possible to arbitrarily change the output frequency and variable characteristics in the optical transmission device used in the communication network. Therefore, it becomes easy to change the frequency in the optical transmission device, and the dramatic man-power reduction can be expected in the case of developing the optical transmission device for a communication standard at a new frequency.

Further, an oscillator for clock, a temperature-compensated oscillator, or the like can be configured as the oscillator 3, and there can be obtained an advantage that an oscillator superior in frequency reproducibility, aging characteristic, and frequency-temperature characteristic can be configured.

### Electronic Apparatus

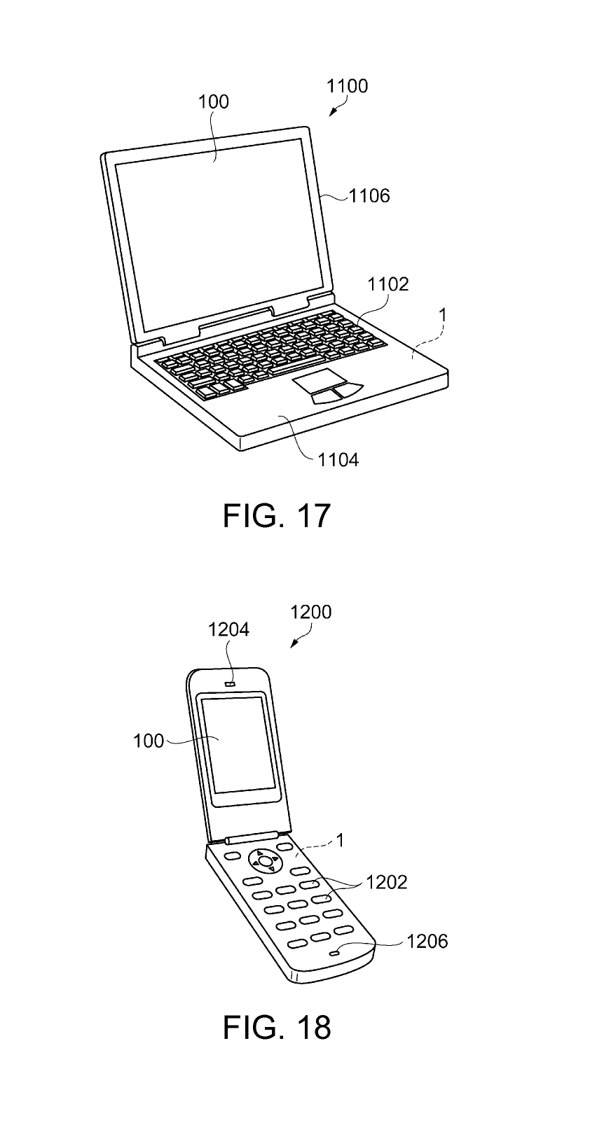

The electronic apparatuses (the electronic apparatuses according to the invention) to which the resonator element according to an embodiment of the invention is applied will now be explained in detail based on FIGS. 17 through 19.

FIG. 17 is a perspective view showing a configuration of a mobile type (or a laptop type) of personal computer as the electronic apparatus equipped with the resonator element according to an embodiment of the invention. In the drawing, the personal computer 1100 includes a main body section 1104 provided with a keyboard 1102, and a display unit 1106 provided with a display section 100, and the display unit 1106 is pivotally supported with respect to the main body section 1104 via a hinge structure. Such a personal computer 1100 incorporates the resonator element 1 functioning as a reference clock or the like.

FIG. 18 is a perspective view showing a configuration of a cellular phone (including PHS) as the electronic apparatus equipped with the resonator element according to an embodiment of the invention. In this drawing, the cellular phone 1200 is provided with a plurality of operation buttons 1202, an ear piece 1204, and a mouthpiece 1206, and the display section 100 is disposed between the operation buttons 1202 and the ear piece 1204. Such a cellular phone 1200 incorporates the resonator element 1 functioning as a reference clock or the like.

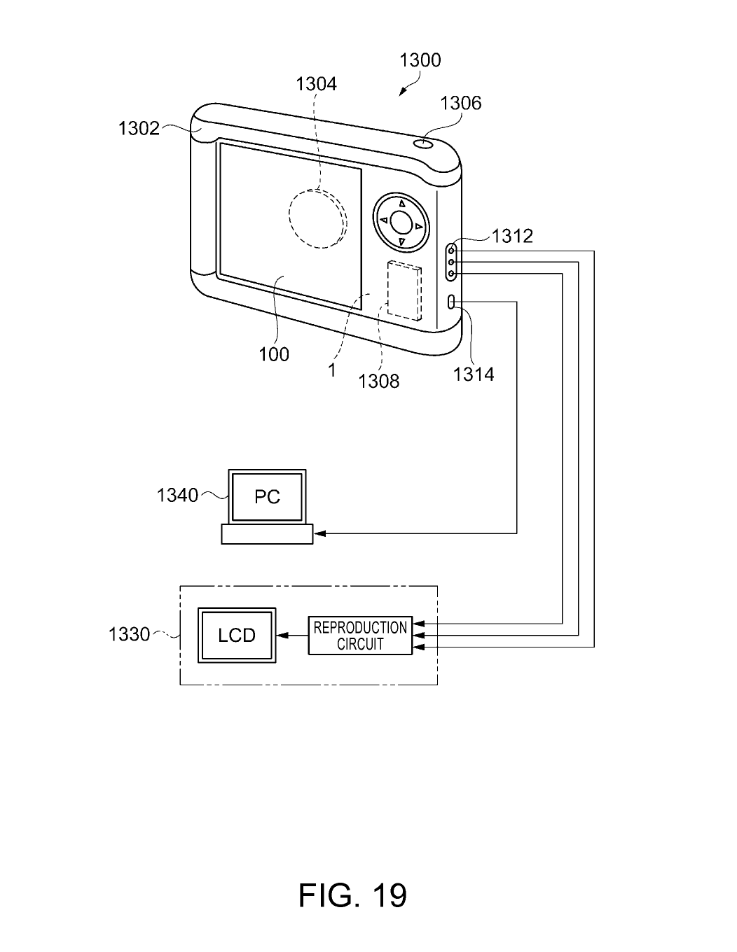

FIG. 19 is a perspective view showing a configuration of a digital still camera as the electronic apparatus equipped with the resonator element according to an embodiment of the invention. It should be noted that the connection with external equipment is also shown briefly in this drawing. Here, an ordinary camera exposes a silver salt film to an optical image of an object, while the digital still camera 1300 performs photoelectric conversion on an optical image of an object by an imaging element such as a CCD (a charge coupled device) to generate an imaging signal (an image signal).

A case (a body) 1302 of the digital still camera 1300 is provided with a display section 100 disposed on the back surface of the case 1302 to provide a configuration of performing display in accordance with the imaging signal from the CCD, wherein the display section 100 functions as a viewfinder for displaying the object as an electronic image. Further, the front side (the reverse side in the drawing) of the case 1302 is provided with a light receiving unit 1304 including an optical lens (an imaging optical system), the CCD, and so on.

When the photographer checks an object image displayed on the display section 100, and then holds down a shutter button 1306, the imaging signal from the CCD at that moment is transferred to and stored in a memory device 1308. Further, the digital still camera 1300 is provided with video signal output terminals 1312 and an input/output terminal 1314 for data communication disposed on a side surface of the case 1302. Further, as shown in the drawing, a television monitor 1330 and a personal computer 1340 are respectively connected to the video signal output terminals 1312 and the input-output terminal 1314 for data communication according to needs. Further, there is adopted the configuration in which the imaging signal stored in the memory device 1308 is output to the television monitor 1330 and the personal computer 1440 in accordance with a predetermined operation. Such a digital still camera 1300 incorporates the resonator element 1 functioning as the reference clock or the like.

It should be noted that, the resonator element 1 according to an embodiment of the invention can also be applied to an inkjet ejection device (e.g. an inkjet printer), a laptop personal computer, a television set, a video camera, a video cassette recorder, a car navigation system, a pager, a personal digital assistance (including one with a communication function), an electronic dictionary, an electric calculator, a computerized game machine, a word processor, a workstation, a video phone, a security video monitor, a pair of electronic binoculars, a POS terminal, a medical device (e.g. an electronic thermometer, an electronic manometer, an electronic blood sugar meter, an electrocardiogram measurement instrument, an ultrasonograph, and an electronic endoscope), a fish detector, various types of measurement instruments, various types of gauges (e.g. gauges for a vehicle, an aircraft, or a ship), and a flight simulator besides the personal computer 1100 (the mobile personal computer) shown in FIG. 17, the cellular phone 1200 shown in FIG. 18, and the digital still camera 1300 shown in FIG. 19.

### Mobile Object

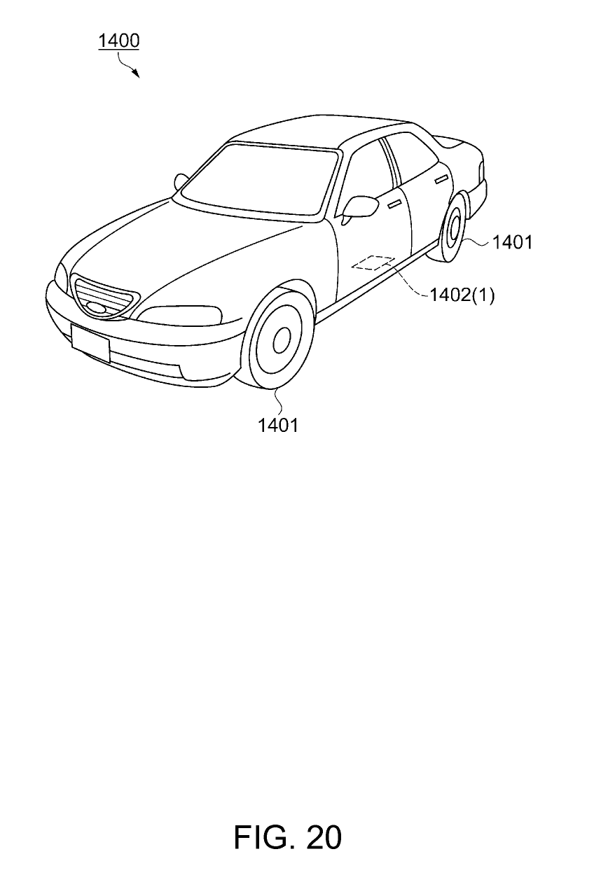

A mobile object (the mobile object according to the invention), to which the resonator element 1 is applied, according to an embodiment of the invention will now be explained based on FIG. 20.

FIG. 20 is a perspective view schematically showing a vehicle 1400 as the mobile object equipped with the resonator element 1. The vehicle 1400 is equipped with an oscillator configured including the resonator element 1 according to an embodiment of the invention. For example, as shown in the drawing, the vehicle 1400 as the mobile object is equipped with the resonator element 1 functioning as the reference clock or the like of an electronic control unit 1402 for controlling tires 1401. Further, as other examples, the resonator element 1 can widely be applied to an electronic control unit (ECU) such as a keyless entry system, an immobilizer, a car navigation system, a car air-conditioner, an anti-lock braking system (ABS), an air-bag system, a tire pressure monitoring system (TPMS), an engine controller, a battery monitor for a hybrid car or an electric car, or a vehicle body attitude control system.

As described above, by providing the resonator element 1 low in capacitance ratio γ to the mobile object, a higher performance mobile object can be provided.

Although the resonator element 1 (1b, 1c, 1d, 1e, 1f, 101a, 101b, and 101c), the resonator 2, the oscillator 3, the electronic apparatus, and the mobile object according to the invention are hereinabove explained based on the embodiments shown in the accompanying drawings, the invention is not limited to these embodiments, but the configuration of each of the components can be replaced with one having an arbitrary configuration with an equivalent function. Further, it is also possible to add any other constituents to the invention. Further, it is also possible to arbitrarily combine any of the embodiments described above.

The entire disclosure of Japanese Patent Application No. 2014-151566 is incorporated by reference herein.

What is claimed is:

1. A resonator element comprising:
a substrate including a first principal surface and a second principal surface opposite to each other;
a first excitation electrode disposed on the first principal surface; and
a second excitation electrode disposed on the second principal surface, the second excitation electrode overlapping an entirety of the first excitation electrode in a plan view,
wherein the first excitation electrode is configured by forming at least one truncated corner to a rectangular shape, and the rectangular shape is configured with a pair of first sides extending in a first direction and a pair of second sides extending in a second direction perpendicular to the first direction, and
wherein when Lx is a maximum length of the first excitation electrode in the first direction and lx is a length of the one truncated corner in the first direction, 13.7%≦(lx/Lx)≦46.0% is satisfied.

2. The resonator element according to claim 1, wherein
the one truncated corner is in an arc shape.

3. The resonator element according to claim 1, wherein
19.1%≦(lx/Lx)≦41.0% is satisfied.

4. The resonator element according to claim 1, wherein
when S1 is an area of the rectangular shape and S2 is an area of the first excitation electrode, 79.8%≦(S2/S1)≦95.3% is satisfied.

5. The resonator element according to claim 4, wherein
81.3%≦(S2/S1)≦93.6%.

6. The resonator element according to claim 1, wherein
when lz is a length of the one truncated corner in the second direction, lx≧lz is satisfied.

7. The resonator element according to claim 1, wherein
when Lz is a maximum length of the first excitation electrode in the second direction, 1.25≦(Lx/Lz)≦1.31 is satisfied.

8. The resonator element according to claim 1, wherein
when S0 is an area of the substrate and S2 is an area of the first excitation electrode, 4%≦(S2/S0)≦50% is satisfied.

9. The resonator element according to claim 1, further comprising:
a first lead electrode disposed on the first principal surface, the first lead electrode being connected to the first excitation electrode, wherein
the first lead electrode overlaps with the second excitation electrode in the plan view.

10. The resonator element according to claim 1, further comprising:
a wall integral with an outer edge of the substrate, the wall being thicker than the substrate.

11. The resonator element according to claim 1, wherein
the substrate has a region that vibrates in a thickness-shear vibration in a thickness-shear vibration direction,
the first direction is along with the thickness-shear vibration direction.

12. The resonator element according to claim 2, wherein
the substrate has a region that vibrates in a thickness-shear vibration in a thickness-shear vibration direction,
the first direction is along with the thickness-shear vibration direction.

13. The resonator element according to claim 3, wherein
the substrate has a region that vibrates in a thickness-shear vibration in a thickness-shear vibration direction,
the first direction is along with the thickness-shear vibration direction.

14. The resonator element according to claim 5, wherein
the substrate has a region that vibrates in a thickness-shear vibration in a thickness-shear vibration direction,
the first direction is along with the thickness-shear vibration direction.

15. A resonator comprising:
the resonator element according to claim 1; and
a package adapted to house the resonator element.

16. A resonator comprising:
the resonator element according to claim 2; and
a package adapted to house the resonator element.

17. An oscillator comprising:
resonator element according to claim 1; and
a circuit element electrically connected to the resonator element.

18. An oscillator comprising:
the resonator element according to claim 2; and
a circuit element electrically connected to the resonator element.

19. An electronic apparatus comprising:
the resonator element according to claim 1.

20. A mobile object comprising:
the resonator element according to claim 1.
